(19) United States
(12) Patent Application Publication
(10) Pub. No.: US 2009/0110842 A1
(43) Pub. Date: Apr. 30, 2009

(54) Boron-based wood preservatives and treatment of wood with boron-based preservatives

(75) Inventors: Peter Vinden, Creswick (AU); Francisco Javier Romero, Mudjimba (AU)

Correspondence Address: GREENLEE WINNER AND SULLIVAN P C, 4875 PEARL EAST CIRCLE, SUITE 200, BOULDER, CO, 80301, US

(73) Assignee: The University of Melboume, Parkville (AU)

(21) Appl. No.: 12/341,897

(22) Filed: Dec. 22, 2008

Related U.S. Application Data
(63) Continuation of application No. 10/481,007, filed on Sep. 8, 2004.

(30) Foreign Application Priority Data
Jun. 15, 2001 (AU) PR 5710/01
Jun. 15, 2001 (AU) PR 5711/01
Jun. 15, 2001 (AU) PR 5712/01

(51) Int. Cl. B05D 1/04; B05D 3/00; B05D 1/18; B05D 1/28; C23C 16/00; B05D 1/02

(52) U.S. Cl. 427/458; 427/317; 427/297; 427/440; 427/254; 427/427.7; 427/428.01; 427/429

(57) ABSTRACT

A process for treating wood comprising applying to the surface of the wood a boron based preservative which reacts with moisture within the wood to form a boron compound and alcohol and subjecting the wood with the applied preservative to a substantially moisture-free and enclosed environment for a period sufficient for the applied preservative to be absorbed into the wood and to produce the boron compound on reaction with the moisture in the wood and for the alcohol by-product of the reaction to be adsorbed within the wood structure.

### FIELD OF THE INVENTION

The present invention relates to processes and preservatives for treating timber or wood based products, hereinafter for convenience referred to simply as wood. More particularly the invention relates to treatment of wood, with a boron compound to act as a preservative and, optionally, to give flame- and/or fire-resistance properties, and is also concerned with the treatment of the wood following application of a boron based preservative.

### BACKGROUND ART

Compounds of boron have been used as preservatives for wood for many years. Since about 1955 the most common method of application of the boron compounds in many countries has been by dipping the wood into an aqueous solution of the compound and allowing the boron compound to diffuse into the wood. For example, the wood may be dipped in 16-18% boric acid solution for a period of about two minutes to give surface application of the preservative and then wrapped to prevent moisture loss for about 6 to 8 weeks while the boric acid preservative diffuses through the wood.

New Zealand patent specification 115464 dated 2 Dec. 1955 proposed an alternative surface application using organic compounds of boron, which it is said may or may not hydrolyse within the wood during or after treatment. This specification proposes the use of a vast number of organic boron compounds and application methods, preferably to wood which is in a dry state either following special drying operations or in equilibrium with its climatic environment. While no methods are exemplified, one proposal is to apply the organic boron compound in the gaseous state with the wood being enclosed in a suitable vessel or envelope, such as of plastic film, from which air is excluded. However there is no discussion of any post-treatment of the wood following application of the preservative. Furthermore, momentary immersion, for periods of about two minutes, of the wood in the boron preservative has remained the standard technique of application.

One boron compound mentioned in NZ-A-115464 as capable of being applied to wood in a gaseous treatment is trimethyl borate. Trimethyl borate (TMB) and some other boron compounds hydrolyse with the wood moisture to release the boron, as the well known preservative boric acid, and alcohol. For example, TMB reacts according to the reaction:

B(OCH₃)₃+3H₂O→H₃BO₃+3CH₃OH.

One problem of applying a wood preservative to the surface of the wood is ensuring that it penetrates sufficiently into the wood for the treatment to be effective. In the case of TMB, if the wood moisture content is too high, the TMB may react to form boric acid before it has diffused into the wood so that the boric acid only appears at and adjacent the surface, rendering the treatment ineffective.

This problem is resolved in Australian patent specification 18324/88 by drying the wood to a reduced moisture content in a treatment vessel, evacuating the treatment vessel, introducing gaseous TMB to the vessel for a period of time before evacuating or venting the vessel to atmosphere, and steaming the treated wood. Steaming is considered necessary in order to restore the moisture content of the wood and to relieve any stresses in the wood caused by the drying, but also has the advantage of rendering inert any remaining TMB on the wood so as to render the wood safe to handle. However, the TMB is applied in excess and is substantially recovered along with moisture and any solvent such as alcohol, as well as alcohol by-product of the TMB reaction with moisture, prior to steaming by evacuating the timber. Excess TMB is recovered because it represents both a health hazard and a flammability hazard on release from the treatment vessel. The condensate from the steam treatment (effectively a mixture of boric acid, alcohol and wood moisture) is a waste product which has a disposal cost.

Drying of wood and its subsequent steam reconditioning are very well known procedures which have been used for many years.

Another way of resolving the problem of ensuring that the conversion of TMB to boric acid is not only at the surface of the wood is proposed in Australian Patent Specification 40465/89 in which the need to pre-dry the wood is said to be avoided by exposing the wood to a vapour of a TMB-methanol azeotrope at a temperature below the boiling point of the methanol by-product of the TMB reaction with moisture in the wood. This is said to reduce the vapour pressure of the methanol by-product allowing improved boron preservative vaporisation and surprisingly improved boric acid deposition. However, the process requires careful temperature control since the boiling point of the azeotrope and of the methanol by-product may be close. The process further requires the recovery of residual vapours since although alcohol is said to be condensed in the wood structure, the alcohol is free to evaporate after the preservative treatment.

Preservative formulations involving boric acid esters dissolved in organic solvents have been described in, for example, NZ Patent No. 115,464 referred to above, U.S. Pat. No. 4,970,201 and International Publication Nos. WO93/02557 and WO94/00988. The choice of organic solvent is important for this type of treatment. Organic solvents used in the wood industry can be classified by polarity. Light organic solvent processes (hereinafter referred to as “LOSP”) involve the use of non-polar solvents, such as, kerosene or white spirits which do not interact with the cell wall. The advantages include non-swelling of the wood, low uptakes and treatment of the wood in its final form. The other types of solvents proposed for boric acid ester formulations are polar solvents which interact with the cell wall. The swelling effect of this interaction requires a drying step after treatment and possible recovery of the solvent. Treatment of dry wood with polar solvents such as methanol results in substantially higher uptakes of the preservative solution as a result of swelling of the cell wall.

The dilution of TMB or a TMB-methanol azeotrope with methanol or other polar solvents also poses the following problems:
(a) methanol is a Class A solvent which means that it is very flammable and requires special equipment designed for its handling;
(b) the preservative solution is susceptible to hydrolysis and requires careful handling;
(c) the TMB-methanol azeotrope has a lower boiling point than TMB and is volatile requiring careful handling procedures both before and after treatment; and
(d) the reaction as shown in equation (1) above produces methanol which has very similar swelling properties to water.

The problem with the use of polar solvents in boron-based preservative solutions such as TMB or the TMB-methanol azeotrope is that they interact with the cell walls and result in swelling of the wood. It is difficult when using these preservative solutions to obtain a high concentration of boric acid in the wood as may be required to impart fire resistant properties.

Different concentrations of boric acid are required in wood to achieve biocidal protection and fire retardant properties. Typically, the boric acid equivalents (hereinafter referred to as “BAE”) required for various applications are as follows:

| | % wt/wt BAE |
|---|---|
| Insect protection | 0.25 |
| Fungicidal protection | 0.75 |
| Fire retardant properties | 7.00 |

The high volumes of TMB required to effect fire retardant properties result in unacceptable swelling of the wood with strength loss. On the other hand, the application of TMB for biocidal protection will usually require dilution of TMB. This may be achieved either by using the TMB-methanol azeotrope or by dilution of TMB or the azeotrope with an alcohol. This poses a similar problem of swelling of the wood as a result of the interaction between the alcohol and the cell wall.

### SUMMARY OF THE INVENTION

According to a first aspect of the present invention there is provided a process for treating wood comprising applying to the surface of the wood, preferably having a reduced moisture content, a boron based preservative which reacts with moisture within the wood to form a boron compound and alcohol and subjecting the wood with the applied preservative to a substantially moisture-free and enclosed environment for a period sufficient for the applied preservative to be absorbed into the wood and to produce the boron compound on reaction with the moisture in the wood and for the alcohol by-product of the reaction to be adsorbed within the wood structure.

Also according to the present invention there is provided wood, whether as timber or wood based products, which has been treated by the process described in the immediately preceding paragraph.

By this aspect of the present invention it has been found that no treatment of the wood is necessary after a limited surface application of the boron based preservative except for subjecting the treated wood to a period in a substantially moisture-free and substantially enclosed environment. During this period, it has been found that the boron based preservative applied to the wood surface may substantially all diffuse into the wood to react with the wood moisture to form the effective boron compound, for example boric acid, and that at least substantially all the alcohol by-product is adsorbed into the wood structure and advantageously fixed in the cell walls. The adsorption process occurs over a prolonged period with the alcohol diffusing in either its condensed state or its vapour state through the wood cross-section, generally mainly in the vapour state. Molecules of the alcohol will eventually diffuse into the microstructure of the cell walls (the so-called transient capillaries) and form an adsorbed monolayer which is hydrogen bonded to the cellulose, hemi-cellulose and lignin in the wood structure. This means that no recovery of the alcohol by-product is necessary and that the wood is safe to handle following the treatment.

Indications are that the formation of the monolayers in the wood structure is a permanent reaction whereby wood can adsorb or fix from 1 to 2% of its weight of alcohol which cannot be recovered even by prolonged evacuation, for example, up to a week. This fixed amount is generally in excess of the alcohol needed to be dissipated following the preservative treatment. However, it is considered likely that the alcohol may be leached out to some extent in water.

It has also most advantageously been found that the alcohol retained in the structure of the wood may remove the need for any reconditioning of the wood by relieving at least some of the residual stresses which may be present in the wood and rendering the wood closer to its equilibrium moisture content. Preferably, however, the reduced moisture content wood to be treated in accordance with the invention is at least substantially stress-free such as, for example, kiln-dried “off-the-shelf” timber.

The substantially moisture free and enclosed environment to which the wood is subjected following application of the boron based preservative is such as to prevent the ingress of moisture into the treated timber, as may be provided from humidity in the atmosphere, and to substantially prevent the evaporation of the applied preservative from the wood into the atmosphere. Various possible environments are envisaged for this post-treatment. For example, the wood with the applied preservative may be introduced to a container or other preformed envelope, such as of steel or plastics, which is then sealed. However, the wood preferably occupies at least a substantial part of the internal volume of the envelope, which may not be possible when the envelope is preformed. Thus, in a preferred embodiment, the treated wood is wrapped to exclude atmosphere and thereby provide the substantially moisture free and enclosed environment. Most advantageously, the wrapping is of plastics material such as polyethylene or, preferably, polyester.

With boron based compounds such as TMB, plastics sheeting which is advantageously used to form the enclosed environment must be carefully selected if the enclosed environment is to be maintained over more than about 24 hours. TMB has very good properties as a solvent for different materials such as waxes, oils, resins, glues and plastics. It also has very low surface tension and low boiling point, properties which produce a high vapour pressure at normal temperatures and which increase the risk of loss of chemicals if the impervious nature of the plastics sheeting is damaged. Polyethylene has been found to be breached by TMB over a period of at least 24 hours, and extensive testing has shown that polyester films provide the optimum properties for forming the enclosed environment, for example polyethylene terephthalate (PET) films. Multilayer films, anti-static films and metallised oxygen barrier films such as 2100, 2100E and 2110E films marketed by 3M as well as metallised multi-layer films incorporating LDPE such as are used in wine bags made by Camvac (Europe) Limited are also appropriate.

One possible difficulty with some of the above plastics sheeting, unless it is to be taped or glued to provide a seal, is that they may not be heat sealable. This difficulty is generally applicable to polyester films, but it has been found that a particularly advantageous film which can be heat sealed is a co-extruded PET film marketed under the Trade Mark MELINEX by ICI. The Melinex film may have a thickness selected as appropriate, for example in the range 15 to 30 μm.

The period of retention in the substantially moisture free and enclosed environment is dependent on factors such as the wood structure, temperature, pressure and the like. Experiments at ambient temperature and pressure indicate only small amounts of unreacted preservative and by-product alcohol vapour after about 24 hours. However, under similar conditions a substantial reduction of both unreacted preservative and alcohol vapour was noted about 6 hours after enclosing the wood in the substantially moisture-free environment. Furthermore, the process involved in hydrolyzing the preservative to alcohol and water and the diffusion of the preservative and alcohol through the wood and uptake into wood structure are processes which can be accelerated by the application of heat. Thus, the period of retention may have to be determined on a trial basis according to the conditions. Generally, the boron based preservative will diffuse through the wood and hydrolyze within a few hours at most followed by complete adsorption of the alcohol by-product. Accordingly, no or negligible odour of the alcohol by-product vapour when the substantially enclosed environment is opened will indicate at least substantial completion of the post treatment.

The wood may conveniently be dispatched for use immediately it is enclosed in the substantially moisture-free environment, minimising the holding time. This means, for example, that a bulk order for treated wood can be supplied in its plastic wrapping for the post-treatment, with the post-treatment continuing to completion of the hydrolysis of the preservative and adsorption of the alcohol by-product during the delivery of the wood and possibly subsequent storage. The reaction and adsorption would normally be expected to be complete within two to three days at most.

The moisture content of the wood is preferably reduced prior to application of a boron based preservative to improve diffusion of the preservative into the wood, particularly to alleviate hydrolysis on the wood surface. Most preferably the moisture content is of the order of about 6% by weight or less of the oven dry weight of the wood. Somewhat higher moisture contents may be appropriate for some wood-based boards or composite products but with solid wood may lead to less efficient use of the preservative, although some additives may make it possible to treat wood with a higher moisture content as described hereafter.

Drying can be achieved by an original drying operation of the wood, preferably entirely separate from the preservative treatment, or may be carried out subsequent to an original drying operation but prior to the preservative treatment from any previous wood moisture content. The application of the preservative and post treatment can be performed with the wood hot, for example out of the kiln or other drying apparatus, or cold.

The boron based preservative which is applied to the surface of the wood may be any boron compound which hydrolyses with the wood moisture to form a preservative-effective boron compound and alcohol including any such organic compound listed in the aforementioned NZ 115464. The boron compound applied to the wood surface may be pure or substantially pure or an azeotrope or other mixture with, for example, alcohol or other solvents. A preferred boron based preservative is TMB or a combination of TMB and methanol at or about the azeotropic composition thereof. An alternative is tri-ethyl borate which hydrolyzes to form ethanol as a by-product and boric acid. Additives may be included in the boron based preservative including, for example, additives to enhance fire-proofing attributes, such as a compatible compound of zinc. Other additives may be included in the boron based preservative to enhance its activity, including a variety of waxes, resins, oils and oil-based pigments which improve the water repellency of timber surfaces and may improve the colour and aesthetic appeal of the treated timber.

Dimension stabilising chemicals can be applied in conjunction with the boron based preservative. For example, one method for the dimensional stabilisation of wood involves the application of acetic anhydride, either in the vapour phase or as a liquid, and heating the wood to 130° C. until an acetylation reactions occur. A major problem with this technique is the corrosive nature of by-products of the reaction, requiring the use of a stainless steel reaction vessel. This problem can be alleviated by applying the acetic anhydride so that the chemical reactions proceed in the enclosed environment. Polyester based films are ideal for this purpose because they are acid resistant and heat resistant. Acetic anhydride is totally miscible with, for example, trimethyl borate and can therefore be applied in the liquid phase or vapour phase by any of the chemical application techniques mentioned hereinafter which can provide the necessary loading of chemical on the surfaces of the wood. The treated wood samples are then placed in the enclosed environment to allow extended diffusion, chemical reaction and chemical dissipation to take place. Trimethyl borate is more volatile than acetic anhydride and diffuses more quickly into the wood. The rate of reaction between chemical and wood moisture is more rapid at higher temperatures and therefore the dissipation reactions can be accelerated by applying heat. Higher temperatures are required to effect acetylation—typically 130° C. The by-products of acetylation (acetic acid) tend to undergo dissipation but the extent of this dissipation has yet to be determined.

The level of protection provided by a treatment in accordance with this aspect of the present invention may be dependent upon the amount of the effective boron compound deposited into the wood. For example, boric acid produced by the hydrolysis of TMB is a broad spectrum preservative. At low retention levels, it provides timber with protection from borer (Anobium punctatum) and Lyctus attack. At higher retention levels it provides protection from termite attack and fungal decay, e.g. dry rot. At higher loadings again, it provides flame/fire-proofing for the wood.

Most proposed applications of TMB for wood treatment involve the use of a lower-boiling azeotrope or mixture of TMB in alcohol. The alcohol (methanol) is a polar solvent which can be absorbed into the wood and, because of the relatively large volume involved, can result in the swelling of the wood. This can be most disadvantageous for some products which are to be treated with preservative, for example panel products such as medium density fibreboard, particle board and so forth, where swelling is an undesirable side effect. The swelling is particularly noticeable where large volumes of preservative are applied to achieve fire and flame resistance of the wood. Not all of the alcohol solvent may be adsorbed into the wood, because of the relatively large volume involved, in which case some recovery of the excess alcohol will be required following application of the preservative in alcohol for flame and fire proofing. This may be direct from the substantially moisture-free and enclosed environment, for example using heat pump technology, preferably vapour recompression. Because of this possible need to recover excess alcohol solvent, there is a preference for applying pure or substantially pure TMB in the process of the invention but TMB is itself a solvent for boric acid or boric oxide and the boron content of TMB can therefore be enhanced simply by refluxing boric oxide and TMB together to produce a boron rich TMB azeotrope which may have advantageous use in the process of this aspect of the invention for fire-proofing wood.

The boron based preservative may be applied to the surface of the wood in any of many known methods, for example pressure impregnation, vacuum/pressure impregnation, dipping, insizing and dipping, soaking, spraying/atomizing/fogging, electrostatic spraying, vaporising, evacuation and vapour or gaseous application, brushing, rolling and compression rolling. The application may be hot or cold. For commercial use, the feasibility of any of these options depends on within-charge retention variability (i.e. variation in the amount of boron based preservative applied to different pieces of wood in the same charge), between-charge retention variability (i.e. the reproducibility of results between different charges given the same treatment schedule) and cost. In addition, it is desirable in accordance with the present invention to avoid excess application of the boron based preservative since there is no recovery of excess materials except, possibly, carrier solvents such as alcohol and kerosene.

The application of boron based preservatives by dipping has been characterised by high retention variability since different amounts of the preservative may be deposited onto different portions of the wood. A typical packet of 100×50 mm radiata pine comprises 24 layers of block-stacked machined timber with fillets placed at the sixth and eighteenth layers, with the packet usually being strapped, and variability in the deposited preservative, both within and between charges, is encountered because of the variation in accessibility to the wood surfaces within the packet. Commonly, dipping is performed for about 2 minutes or more in an attempt to even up the application of the preservative. However, surprisingly, it has been found that variability in application of the preservative can be substantially reduced by reducing the dipping time to about 1 minute or less, preferably about 30 seconds or less and most preferably about 15 seconds or less. In experiments, it has been found that adequate application of preservative, in the form of substantially pure TMB, was achieved with minimum variability by reducing the dipping time of the charge to approximately 2 seconds. In practice, it is accepted that there may be commercial difficulties in restricting the dipping time of a substantial charge to approximately 2 seconds all over, but it will be appreciated that the proposed reduced dipping times, particularly 15 seconds or less will substantially reduce the uptake of chemical into the coarse capillary structure of the wood and limit uptake or retention of chemical to the surface of the wood, and thereby enhance the overall process of the invention.

The preservative used for dipping or other non-vapour or gaseous application may be volatile at ambient temperature and advantageously the vapour pressure of the preservative is kept low by refrigerating the bath of preservative. Additionally, the bath may be sealed to prevent the escape of any vapours and, in a preferred embodiment, the wood with the preservative applied is introduced to the substantially moisture free and enclosed environment within the sealed atmosphere of the bath.

Following treatment of the wood in accordance with this aspect of the present invention, the wood may be surface treated, for example, with a resin, to immobilize the boron, that is to render the boron leach resistant.

It has been found that the use of a light organic solvent wood preservative containing a boron compound may allow wood to be treated at normal moisture contents i.e., 10 to 14%. That is the amount of solvent used is reduced thereby minimising flammability hazards and costs. Thus, according to a second aspect of the invention there is provided a light organic solvent wood preservative comprising a trialkyl borate and a non-polar carrier. This LOSP is preferably used in the process of the first aspect of the invention.

Suitable trialkyl borates include those having C₁₋₂₀ alkyl, preferably C₁₋₉ alkyl and more preferably C₁₋₆ alkyl groups. A particularly preferred trialkyl borate is TMB which reacts with moisture present in the wood according to equation (1) above to form boric acid and methanol. An alternative trialkyl borate is triethyl borate which hydrolyses to form boric acid and ethanol.

The non-polar carrier may include a non-polar solvent, such as, aliphatic or aromatic hydrocarbons and heterocycles or derivatives thereof, for example, kerosene, petroleum and turpentine; an oil; or mixtures thereof. While oil is slightly more expensive than other non-polar carriers, there are a number of advantages in its use. Oil has low volatility and odour and therefore requires no recovery. The efficacy of the preservative is also enhanced by the use of oil in a synergistic manner by reducing water ingress into the wood thereby delaying hydrolysis of the trialkyl borate. Oil also improves the aesthetic appearance of wood and reduces surface checking. It will be appreciated that the selection of the non-polar carrier may provide the wood with enhanced properties and reduce the amount of non-polar carrier needed to achieve total treatment of the wood.

Thus, in another embodiment of this aspect of the invention the light organic solvent wood preservative comprises a trialkyl borate, a non-polar solvent and an oil.

Additives may also be included in the wood preservative of this aspect of the present invention. Suitable additives are selected from water repellents, such as, waxes, resins or polymers, for example, polyethylene glycol; dimensional stabilisers, such as, acetic anhydride; fire retardants, such as, zinc compounds; mildewicides/fungicides; insecticides, such as, pyrethroids or triazoles; mouldicides; dyes and pigments.

The wood, generally having a higher moisture content of from 10-14% may be any timber or wood based product, such as, refractory timber, softwoods or hardwoods. The softwood may include spruces, firs, cypresses or pine species, such as, P. Radiata, for example, heartwood or sapwood. Heartwood is the most difficult part of P. Radiata to treat with preservatives. The hardwoods may include eucalypts, oak, beech, poplar, maples, willows, elms or ashes.

As discussed above, the wood may be treated at moisture contents above 6% which includes the moisture content of 10 to 14% which is regarded as optimum in the wood industry for drying and using wood in construction applications. Alternatively, as previously discussed the moisture content of the wood may be reduced prior to application of the preservative to about 6% or less to improve diffusion of the preservative into the wood, particularly to alleviate hydrolysis on the wood surface. Somewhat higher moisture contents may be appropriate for some wood-based boards or composite products, but with solid wood may lead to less efficient use of the preservative. Drying can be achieved as discussed above. The preservative treatment according to this aspect of invention can be performed with the wood hot, for example out of the kiln or other drying apparatus or cold because the presence of the non-polar carrier in the preservative means that there is no swelling of the wood because the non-polar carrier does not interact with the cell walls. This in turn reduces the rate of hydrolysis of the trialkyl borate so that the formation of boric acid and alcohol is retarded and will still penetrate into the wood.

The preservative may be applied to the surface of the wood by any suitable known method as already discussed. In addition, it is desirable in accordance with this aspect of the present invention to avoid excess application of the preservative since there is no recovery of excess materials except, possibly, the non-polar carrier.

By this aspect of the present invention, it has been found that no treatment of the wood is necessary after application of the preservative except for allowing sufficient time for the preservative to diffuse into the wood, preferably in a substantially moisture free and enclosed environment as discussed for the first aspect of the invention. The non-polar carrier which is substantially immiscible and repellent to water protects the trialkyl borate from contact with water contained in the wood cell wall. This enables the trialkyl borate to become dispersed throughout the wood before it reacts with the residual wood moisture to form boric acid and alcohol which is adsorbed into the wood structure and fixed in the cell walls. The adsorption process again generally occurs over a prolonged period with the alcohol diffusing in either its condensed state or its vapour state through the wood cross-section, generally mainly in the vapour state. Although no recovery of the alcohol is necessary and that the wood is safe to handle following the treatment, if desired the non-polar carrier may be recovered.

The use of non-polar carriers in the preservative of this aspect of the present invention typically results in an uptake of carrier of 30 l/m³ because there is substantially no interaction between the carrier and the wood (i.e. there is no swelling). This may be compared with 150 l/m³ if polar solvents, such as, methanol are used. It has been found that there is a synergy in using non-polar carriers in applying TMB by vacuum/pressure impregnation. Normally, very low moisture contents are required for the application of TMB whether by liquid or vapour phase treatment, typically less than 6% moisture content, to achieve total preservative penetration. The application of TMB in non-polar carriers facilitates treatment of wood having a moisture content of greater than 6%. Thus, there are no special drying requirements for the wood to effect total TMB penetration. Furthermore, as the treatment may be conducted at higher wood moisture contents and there is total TMB penetration, the TMB is hydrolysed during treatment so that no recovery of the non-polar carrier is required after treatment.

Other advantages of this aspect of the present invention include:
(a) the ability to include other additives as described above to effect synergy and further reduce the quantity of trialkyl borate required to effect fire retardant properties and biocidal protection to the wood;
(b) the use of Class B solvents which have reduced flammability hazards and enable treatment to be conducted in conventional LOSP treatment plants; and
(c) the ability to treat wood in its final shape and form.

The level of protection provided by a treatment in accordance with the present invention may be dependent upon the amount of boric acid deposited into the wood. For example, as already discussed, boric acid produced by the hydrolysis of TMB is a broad spectrum preservative. At low retention levels, it provides wood with protection from borer (Anobium punctatum) and Lyctus attack. At higher retention levels it provides protection from termite attack and fungal decay, e.g., dry rot. At higher loadings again, it provides flame/fire-proofing for the wood.

Following treatment of the wood in accordance with this aspect of the present invention, the wood may be surface treated, for example, with a resin, to immobilise the boron, that is to render the boron leach resistant.

According to a third aspect of the invention there is provided a boron-based wood preservative which will enable high or low concentrations of boric acid to be incorporated into the wood, but which avoids swelling of the wood so that drying and/or recovery steps are not required after the treatment. That is there is provided a wood preservative which is prepared by reacting a boron-based preservative with a boric oxide.

Suitable boron-based preservatives include those disclosed in “The Chemistry of Wood Preservation” (1991), Ed. R. Thompson., Pub. The Royal Society of Chemistry Cambridge, such as, boron esters, for example, trisubstituted borates. Examples of trisubstituted borates include TMB, triethyl borate, tri-n-propyl borate, triisopropyl borate, tri-n-butyl borate, tri (hexylene glycol) borate, triphenyl borate, triisobutyl borate, tri-n-amyl borate, tri-(octelycene glycol) biborate, tri-sec-butyl borate, tri-n-octyl borate, tri-n-dodecyl borate, tri-tert-butyl borate, tri-3-pentyl borate, tri-3-heptyl borate, trialkyl amine borate, trialkanolamine borate and triphenyl borate. A preferred boron-based preservative is TMB.

The wood preservative is advantageously prepared by reacting boric oxide with the boron-based preservative and refluxing the mixture until it dissolves. The exact identity of the product formed has not yet been identified, but is predicted to be a boroxine or a polyborate or mixtures thereof. The possible products formed by the reaction will now be described using TMB as the boron-based preservative.

The reaction of boric oxide and TMB in appropriate proportions results in the production of trimethoxy boroxine as shown in equation (2):

(CH₃O)₃B+B₂O₃→(CH₃OBO)₃ (2)

Trimethoxy boroxine has the following structure:

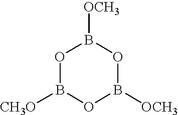

One of the most important properties of the low molecular weight boroxines is their solubility in non-polar solvents. In addition, the amount of boric acid they deliver following hydrolysis makes these compounds useful as a wood preservative for a wide range of applications. The hydrolysis of trimethoxy boroxine is shown in equation (3):

(CH₃O₃)B₃+9H₂O→3H₃BO₃+3CH₃OH (3)

The hydrolysis reaction indicates that more water is needed to hydrolyse one molecule of boroxine than is needed to hydrolyse TMB. It also shows that the amount of boric acid produced is 112% the initial weight of the boroxine. The methanol produced in comparison to the hydrolysis of TMB is also substantially lower. The hydrolysis is instantaneous and is therefore similar to TMB. Furthermore, the boiling point of trimethoxy boroxine is 130° C. which makes this compound easy to handle during preservative treatment.

Thus, a wood preservative which comprises a boroxine is also provided as is a process for wood preservation which comprises treating the wood with a boroxine.

Preferably, the boroxine has a general formula (I):

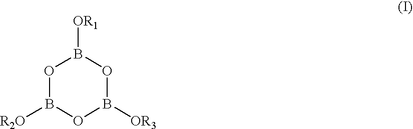

wherein R₁, R₂, and R₃ may be the same or different and are selected from optionally substituted alkyl, optionally substituted alkenyl, optionally substituted alkynyl, optionally substituted cycloalkyl, optionally substituted cycloalkenyl, optionally substituted cycloalkynyl, optionally substituted aryl or optionally substituted heterocycyl.

The term “alkyl” used either alone or in compound words such as “optionally substituted alkyl” or “optionally substituted cycloalkyl” denotes straight chain, branched or mono- or poly-cyclic alkyl, preferably C₁₋₃₀ alkyl or cycloalkyl. Examples of straight chain and branched alkyl include methyl, ethyl, propyl, isopropyl, butyl, isobutyl, sec-butyl, tert-butyl, amyl, isoamyl, sec-amyl, 1,2-dimethylpropyl, 1,1-dimethylpropyl, hexyl, 4-methylpentyl, 1-methylpentyl, 2-methylpentyl, 3-methylpentyl, 1,1-dimethylbutyl, 2,2-dimethylbutyl, 3,3-dimethylbutyl, 1,2-dimethylbutyl, 1,3-dimethylbutyl, 1,2,2-trimethylpropyl, 1,1,2-trimethylpropyl, heptyl, 5-methylhexyl, 1-methylhexyl, 2,2-dimethylpentyl, 3,3-dimethylpentyl, 4,4-dimethylpentyl, 1,2-dimethylpentyl, 1,3-dimethylpentyl, 1,4-dimethylpentyl, 1,2,3-trimethylbutyl, 1,1,2-trimethylbutyl, 1,1,3-trimethylbutyl, octyl, 6-methylheptyl, 1-methylheptyl, 1,1,3,3-tetramethylbutyl, nonyl, 1-, 2-, 3-, 4-, 5-, 6- or 7-methyloctyl, 1-, 2-, 3-, 4- or 5-ethylheptyl, 1-, 2- or 3-propylhexyl, decyl, 1-, 2-, 3-, 4-, 5-, 6-, 7- and 8-methylnonyl, 1-, 2-, 3-, 4-, 5- or 6-ethyloctyl, 1-, 2-, 3- or 4-propylheptyl, undecyl 1-, 2-, 3-, 4-, 5-, 6-, 7-, 8- or 9-methyldecyl, 1-, 2-, 3-, 4-, 5-, 6- or 7-ethylonyl, 1-, 2-, 3-, 4- or 5-propyloctyl, 1-, 2- or 3-butylheptyl, 1-pentylhexyl, dodecyl, 1-, 2-, 3-, 4-, 5-, 6-, 7-, 8-, 9- or 10-methylundecyl, 1-, 2-, 3-, 4-, 5-, 6-, 7- or 8-ethyldecyl, 1-, 2-, 3-, 4-, 5- or 6-propylnonyl, 1-, 2-, 3- or 4-butyloctyl, 1-2 pentylheptyl and the like.

The term “alkenyl” used either alone or in compound words such as “optionally substituted alkenyl” or optionally substituted cycloalkenyl” denotes groups formed from straight chain, branched or mono- or poly-cyclic alkenes including ethylenically mono- or poly-unsaturated alkyl or cycloalkyl groups as defined above, preferably C₂₋₃₀ alkenyl. Examples of alkenyl include vinyl, allyl, 1-methylvinyl, butenyl, iso-butenyl, 3-methyl-2-butenyl, 1-pentenyl, cyclopentenyl, 1-methyl-cyclopentenyl, 1-hexenyl, 3-hexenyl, cyclohexenyl, 1-heptenyl, 3-heptenyl, 1-octenyl, cyclooctenyl, 1-nonenyl, 2-nonenyl, 3-nonenyl, 1-decenyl, 3-decenyl, 1,3-butadienyl, 1,4-pentadienyl, 1,3-cyclopentadienyl, 1,3-hexadienyl, 1,4-hexadienyl, 1,3-cyclohexadienyl, 1,4-cyclohexadienyl, 1,3-cycloheptadienyl, 1,3,5-cycloheptatrienyl, 1,3,5,7-cyclooctatetraenyl and the like.

The term “alkynyl” used either alone or in compound words, such as, “optionally substituted alkynyl” and “optionally substituted cycloalkynyl” denotes groups formed from straight chain, branched, or mono- or poly-cyclic alkynes. Examples of alkynyl include ethynyl, 1-propynyl, 1- and 2-butynyl, 2-methyl-2-propynyl, 2-pentynyl, 3-pentynyl, 4-pentynyl, 2-hexynyl, 3-hexynyl, 4-hexynyl, 5-hexynyl, 10-undecynyl, 4-ethyl-1-octyn-3-yl, 7-dodecynyl, 9-dodecynyl, 10-dodecynyl, 3-methyl-1-dodecyn-3-yl, 2-tridecynyl, 11-tridecynyl, 3-tetradecynyl, 7-hexadecynyl, 3-octadecynyl and the like.

The term “aryl” used either alone or in compound words such as “optionally substituted aryl” denotes single, polynuclear, conjugated and fused residues of aromatic hydrocarbons. Examples of aryl include phenyl, biphenyl, terphenyl, quarterphenyl, phenoxyphenyl, naphthyl, tetrahydronaphthyl, anthracenyl, dihydroanthracenyl, benzanthracenyl, dibenzanthracenyl, phenanthrenyl and the like.

The term “heterocyclyl” used either alone or in compound words such as “optionally substituted heterocyclyl” denotes mono- or poly-cyclic heterocyclyl groups containing at least one heteroatom atom selected from nitrogen, sulphur and oxygen. Suitable heterocyclyl groups include N-containing heterocyclic groups, such as, unsaturated 3 to 6 membered heteromonocyclic groups containing 1 to 4 nitrogen atoms, for example, pyrrolyl, pyrrolinyl, imidazolyl, pyrazolyl, pyridyl, pyrimidinyl, pyrazinyl, pyridazinyl, triazolyl or tetrazolyl;
saturated 3 to 6-membered heteromonocyclic groups containing 1 to 4 nitrogen atoms, such as, pyrrolidinyl, imidazolidinyl, piperidino or piperazinyl;
unsaturated condensed heterocyclic groups containing 1 to 5 nitrogen atoms, such as, indolyl, isoindolyl, indolizinyl, benzimidazolyl, quinolyl, isoquinolyl, indazolyl, benzotriazolyl or tetrazolopyridazinyl;
unsaturated 3 to 6-membered heteromonocyclic group containing an oxygen atom, such as, pyranyl or furyl;
unsaturated 3 to 6-membered heteromonocyclic group containing 1 to 2 sulphur atoms, such as, thienyl;
unsaturated 3 to 6-membered heteromonocyclic group containing 1 to 2 oxygen atoms and 1 to 3 nitrogen atoms, such as, oxazolyl, isoxazolyl or oxadiazolyl;
saturated 3 to 6-membered heteromonocyclic group containing 1 to 2 oxygen atoms and 1 to 3 nitrogen atoms, such as, morpholinyl;
unsaturated condensed heterocyclic group containing 1 to 2 oxygen atoms and 1 to 3 nitrogen atoms, such as, benzoxazolyl or benzoxadiazolyl;
unsaturated 3 to 6-membered heteromonocyclic group containing 1 to 2 sulphur atoms and 1 to 3 nitrogen atoms, such as, thiazolyl or thiadiazolyl;
saturated 3 to 6-membered heteromonocyclic group containing 1 to 2 sulphur atoms and 1 to 3 nitrogen atoms, such as, thiazolidinyl; and
unsaturated condensed heterocyclic group containing 1 to 2 sulphur atoms and 1 to 3 nitrogen atoms, such as, benzothiazolyl or benzothiadiazolyl.

In this specification “optionally substituted” means that a group which may or may not be further substituted with one or more groups selected from alkyl, alkenyl, alkynyl, aryl, halo, haloalkyl, haloalkenyl, haloalkynyl, haloaryl, hydroxy, alkoxy, alkenyloxy, alkynyloxy, aryloxy, carboxy, benzyloxy haloalkoxy, haloalkenyloxy, haloalkynyloxy, haloaryloxy, nitro, nitroalkyl, nitroalkenyl, nitroalkynyl, nitroaryl, nitroheterocyclyl, azido, amino, alkylamino, alkenylamino, alkynylamino, arylamino, benzylamino, acyl, alkenylacyl, alkynylacyl, arylacyl, acylamino, acyloxy, aldehydro, alkylsulphonyl, arylsulphonyl, alkylsulphonylamino, arylsulphonylamino, alkylsulphonyloxy, arylsulphonyloxy, heterocyclyl, heterocycloxy, heterocyclylamino, haloheterocyclyl, alkylsulphenyl, arylsulphenyl, carboalkoxy, carboaryloxy, mercapto, alkylthio, arylthio, acylthio and the like.

A particularly preferred boroxine for use in the present invention has the formula (I) as defined above wherein R₁, R₂ and R₃ are C₁₋₁₀ alkyl or phenol.

It will be appreciated that other methods may be used to prepare the boroxine, such as, for example, the methods disclosed in Steinberg, H., (1964), “Organoboron chemistry”, (First Edition ed.)., Interscience Publishers, pp 950.

Polyborates formed from boroxines have the general formula (II):

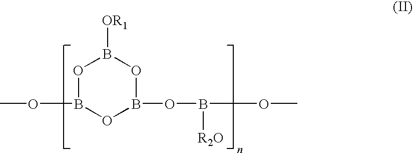

wherein R₁ and R₂ may be the same or different and are as defined in formula (I) above.

Polyborates may be formed when boric oxide is reacted with trimethyl borate or trimethoxy boroxine in appropriate proportions. As the ratio of boron/alkyl groups increases, the polyborate starts to form complexes and becomes more viscous. In essence an alkoxy group becomes buried in a boron oxide type matrix.

The advantages of polyborates include their higher boron content and slower hydrolysis. Thus, when used as a wood preservative in non-polar or polar solvents, good penetration can be achieved.

Accordingly, there is further provided a wood preservative which comprises a polyborate and a process for wood preservation which comprises treating the wood with a polyborate.

Preferably, the polyborate has the general formula (II) defined above, more preferably the polyborate compound has the general formula (II) wherein R₁ and R₂ are C₁₋₁₀ alkyl or phenol.

The present invention still further provides a wood preservative comprising a boroxine and a polyborate. The present invention still further extends to a process for wood preservation which comprises treating the wood with a boroxine and a polyborate.

The wood preservative may be applied to the wood alone, in the form of an emulsion or in combination with a suitable carrier which may be polar or non-polar and selected from water, alcohols, aromatic or aliphatic solvents or oils. A preferred polar carrier is methanol or TMB. Preferred non-polar carriers include kerosene, petroleum, turpentine, oil or mixtures thereof. In the case of polyborates, the dilution of the wood preservative provides lower viscosity solutions which are capable of vacuum pressure impregnation.

Alternatively, the wood preservative may be used as a solid preservative, for example, in the form of a rod which may be inserted into the wood or a paste which may be applied to the surface of the wood so as to impart the appropriate fire retardant properties or biocidal protection. In particular, solid polyborates have been found to be very suitable for the treatment of wood which may be infected with decay fungi. The solid preservative may be shaped and applied into pre-drilled holes or can be melted at relatively low temperatures and injected into cavities. The particular advantages of the solid polyborates compared to other solid boron compounds include their stability, relatively low manufacturing costs and fast rates of dissolution and diffusion under high wood moisture leading to conditions normally suitable for decay.

Additives may also be included in the wood preservative of the present invention. Suitable additives are selected from water repellants, such as, waxes, resins or polymers, such as polyethylene glycol; dimensional stabilisers, such as, acetic anhydride; fire retardants, such as, zinc compounds; mildewicides; fungicides/insecticides; such as pyrethroids or triazoles; mouldicides; dyes and pigments.

The wood may be any timber or wood based product, such as, refractory timber, softwoods or hardwoods. The softwood may include spruces, firs, cypresses or pine species, such as, P. Radiata, for example, heartwood or sapwood. Heartwood is the most difficult part of P. Radiata to treat with preservatives. The hardwoods may include eucalypts, oak, beech, poplar, maples, willows, elms or ashes.

The wood may be treated at moisture contents above 6% which includes the normal moisture content of 10 to 14% which is regarded as optimum in the wood industry for drying and using wood in construction applications. Alternatively, the moisture content of the wood may be reduced prior to application of the preservative to about 6% or less to improve diffusion of the preservative into the wood, particularly to alleviate hydrolysis on the wood surface. Somewhat higher moisture contents may be appropriate for some wood-based boards or composite products, but with solid wood may lead to less efficient use of the preservative. Drying can be achieved by an original drying operation of the wood, preferably entirely separate from the preservative treatment, or may be carried out subsequent to an original drying operation but prior to the preservative treatment from any previous wood moisture content. The preservative and treatment can be performed with the wood hot, for example out of the kiln or other drying apparatus or cold.

The preservative may be applied to the surface of the wood in any suitable known method as previously described, for example pressure impregnation, vacuum/pressure impregnation, dipping, insizing and dipping, soaking, spraying/atomising/fogging, electrostatic spraying, vaporising, evacuation and vapour or gaseous application, brushing, rolling and compression rolling. The application may be hot or cold. For commercial use, the feasibility of any of these options depends on the within-charge retention variability (i.e. variation in the amount of preservative applied to different pieces of wood in the same charge), between-charge retention variability (i.e. the reproducibility of results between different charges given the same treatment schedule) and cost. In addition, it is desirable in accordance with the present invention to avoid excess application of the preservative since there is no recovery of excess materials except, possibly, the carrier solvents such as alcohol and kerosene.

The low amount of alcohol present in the preservative enables it to become dispersed throughout the wood before it reacts with the residual wood moisture to form boric acid and alcohol which is adsorbed into the wood structure and fixed in the cell walls. The adsorption process occurs over a prolonged period with the alcohol diffusing in either its condensed state or its vapour state through the wood cross-section, generally mainly in the vapour state. Molecules of the alcohol will eventually diffuse into the microstructure of the cell walls (the so-called transient capillaries) and form an adsorbed monolayer which is hydrogen bonded to the cellulose, hemi-cellulose and lignin in the wood structure. This means that no recovery of the alcohol is necessary and that the wood is safe to handle following the treatment.

The main advantages of the wood preservatives of this aspect of the present invention arise from their low alcohol content, which facilitates treatment of wood without swelling and strength loss of the product. Further advantages of the preservatives of the present invention relate to their lower cost compared to other boron compounds, their high boiling points and lower vapour pressures which reduce handling difficulties.

The level of protection provided by a treatment in accordance with the present invention may be dependent upon the amount of boric acid deposited into the wood. For example, boric acid produced by the hydrolysis of TMB is a broad spectrum preservative. At low retention levels, it provides wood with protection from borer (Anobium punctatum) and Lyctus attack. At higher retention levels it provides protection from termite attack and fungal decay, e.g., dry rot. At higher loadings again, it provides flame/fire-proofing for the wood.

### BRIEF DESCRIPTION OF THE DRAWING

Various examples of a process in accordance with embodiments of the invention will now be described by way of example only with reference to the accompanying drawings in which:

FIG. 1 is a graph illustrating the advantages of reducing the temperature of the preservative applied to wood by dipping, taken from Table 1; and

FIG. 2 is a set of graphs illustrating the reducing TMB and methanol concentrations in the enclosed environment after momentary dipping of radiata pine in TMB.

### EXAMPLES

Examples 1 to 5 illustrate embodiments of the first aspect of the invention.

### Example 1

Two samples of Eucalyptus Obliqua (Messmate) were kiln dried to 6% moisture content, end-sealed with epoxy resin and then impregnated with pure trimethyl borate by dipping at ambient temperature. The wood samples were subjected to an initial vacuum of −65 kPa (gauge) for 5 minutes. The samples were removed from the dipping solution and immediately weighed to determine chemical uptake. The samples were then sealed in a polythene envelope to allow diffusion of chemical and dissipation of alcohol into the wood structure. After 24 hours the samples were removed from the envelope and then cross-cut and spot-tested with curcumin and salicylic acid to determine boron penetration. After the holding period of 24 hours there were no fumes of alcohol or TMB emitted from the wood block. Preservative retention (kgs TMB) was approximately 4.8 kg/m3 and spot-testing of preservative penetration indicate 8 mm depth of penetration.

Matched samples of messmate, treated by dipping for 1 minute achieved uptakes of 3.6 kg/m3 and similar preservative penetration.

### Example 2

Sixteen samples of radiata pine measuring 100×50 mm in cross-section and dried to 6% moisture content were end-sealed with epoxy resin and left in pure trimethyl borate for 30 seconds. Preservative retention measured from weights before and after dipping indicated:

A mean charge retention of TMB of 13.4 kg/m3
Standard deviation (sd) 6.4
Coefficient of variation (CV %) 48.1

The samples were sealed in a polythene envelope and examined after 2 hours, 6 hours, 12 hours and 24 hours. Spot-testing of preservative penetration indicated substantial penetration of the chemical within 2 hours. However fumes of TMB were still very evident. Alcohol fumes were still present after 6 hours of storage but were totally dissipated after 24 hours.

The high variability in retention between pieces indicated that the traditional dip treatment would be unsuitable as a treatment method. Further statistical analysis indicated that the variability in uptake could be correlated with the natural variability of the timber.

Further research was undertaken in an attempt to reduce within charge retention variability. The results of treatment using matched materials and parameters to the 30 second dip process described above except for a 2 second immersion period are summarised below.

| Mean charge retention: | 8.3 kg/m3 TMB |
|---|---|
| sd | 1.99 |
| CV % | 24 |

The within charge retention variability was substantially lower and within the limits of providing an economic option for treatment. Spot-testing of preservative penetration confirmed total penetration of the cross-section.

### Example 3

Similar samples of radiata pine prepared as per example 2 were left with no envelope. Total chemical penetration was achieved. However there was substantial loss of chemical due to hydrolysis on the surfaces of the timber due to reaction with moisture from the air and loss of chemical due to evaporation.

### Example 4

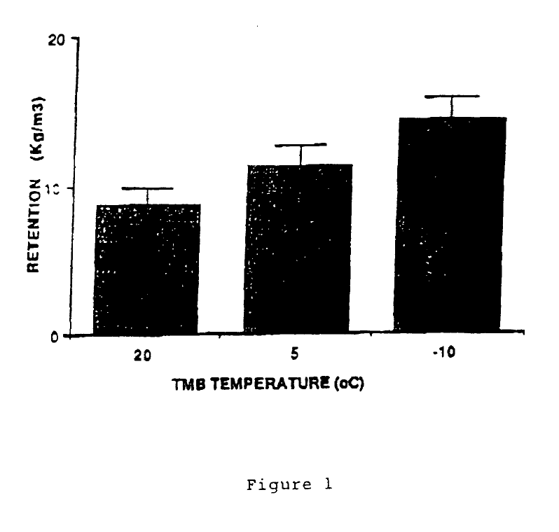

Treatments were conducted as per example 2 by dipping for 30 seconds. In these experiments the solution of TMB was at 20° C. as in Example 2 and was cooled to 5° C. and −10° C. The results of these trials are summarised in FIG. 1. As the solution was cooled there was higher chemical uptake. This was due to contraction of air in the wood during dipping leading to a pressure differential and therefore higher uptake. This effect is similar to the hot and cold bath method of treatment.

Cooling of TMB was considered beneficial because of a reduction in vapour pressure and therefore a lessening of the potential flammability hazard of the chemical.

TABLE 1
Average of chemical retention (kg/m3), standard deviation and
standard error of blocks treated by dipping 30 seconds
in different solution temperatures of TMB

| | | Average | | |
|---|---|---|---|---|
| Solution | Number | Chemical | | |
| Temperature | of | Uptake | Standard | Standard |
| ° C. | Replicates | Kg/m3 | Deviation | Error |
| 20 | 24 | 14.738 | 9.543 | 1.948 |
| 5 | 24 | 19.16 | 10.743 | 2.193 |
| −10 | 24 | 24.122 | 12.534 | 2.558 |

### Example 5

This example studied the emission and dissipation of TMB and methanol during the process using a desiccator to provide the enclosed environment.

In total 18 blocks of tangentially oriented radiata pine sapwood (45 mm×65 mm×80 mm) were tested. Variables tested included moisture content and temperature. The temperatures tested were 20° C. and 40° C. Board moisture contents were 12%, 6% and 3%. All blocks were treated with trimethyl borate at −10° C. by momentary immersion for 1 minute. The blocks were then placed into respective desiccators. The desiccators were placed into a number of incubators at different temperatures. The volume of each desiccator was 1520 ml. The ratio between the volume of the desiccator and the contained wood sample was 6.5:1. Four millilitre samples were taken from the head space right after the samples were placed into the desiccators. Samples were then taken at 5 minute, 20 minute, 40 minute, 1 hour, 2 hour, 4 hour, 8 hour, 1 day, 2 days, 4 day and 6 day intervals. At the same time the weight of samples were measured with minimum disturbance of the environment inside the desiccator.

Periodic sampling of the environment containing the treated wood blocks was achieved using a 10 ml gas tight syringe with a strong needle to penetrate the plug in the desiccator. A magnet was attached to the bottom of the wood sample and a stirrer placed underneath the desiccator. Circular movement of the wood within the desiccator ensured even distribution of any vapours. The sample obtained by the syringe was scrubbed into 2 ml of distilled water in a 3 ml vial. The water was drawn into the syringe first and shaken vigorously. The solution was then placed into the vial and shaken again. This operation was repeated twice. Solutions were analysed for boric acid by high liquid performance chromatography (HPLC) using an anion-R column, and a conductivity detector. The carrier used in the HPLC to elute the samples was 5 mM of sodium hydroxy and 0.1 mM of sodium benzoate. The flow was 1 ml/minute. The peaks were compared with external standards of boric acid.

The same samples were analysed for methanol content. This was done using GLC. The methodology used was the same as given above. Before injecting the sample in the GLC, boric acid was eliminated. This was achieved by exposing the sample to anion exchange resin marketed by Bio-rad under the trade name “AG 1 strong anion exchange resin”, using the batch method. During preliminary experiments it was noted that TMB reduced the sensitivity, resolution and efficacy of the column used to detect alcohols, thus reducing the life of the column. Because TMB produced boric acid when hydrolysed this procedure was followed as a safety precaution. The data was tabulated and then analysed using a statistical and graphic computer software package.

When the levels of TMB and methanol reached a constant value in the desiccator environment, the samples were weighed and measured. The samples were then placed into a bell jar and scrubber assembly in which the flow was set at 0.25 l per minute. The absorbent used was water. A second fluid scrubber ensured the total collection of methanol.

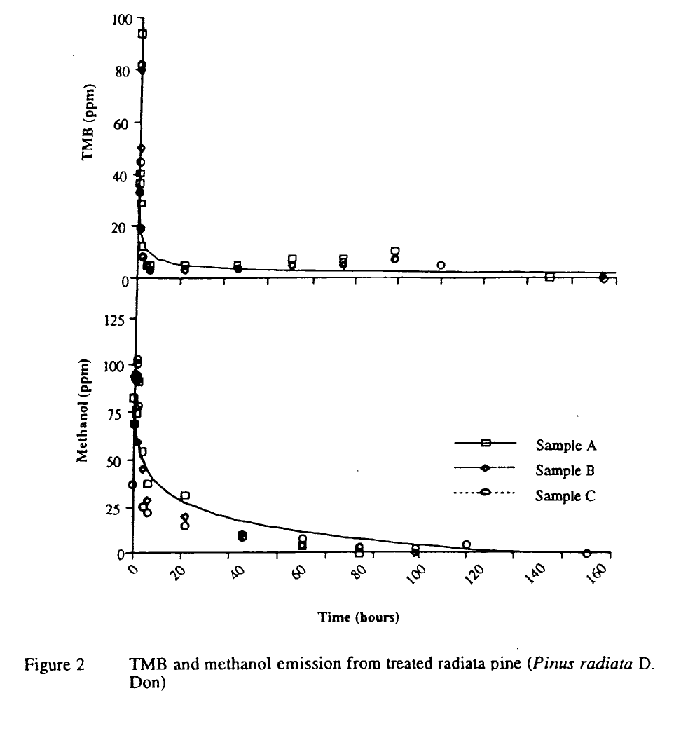

The rate of dissipation of methanol and TMB in the environment is illustrated in FIG. 2 from which the ratio of boric acid:methanol can also be estimated. Both methanol and TMB decreased with time. However there were significant differences in the shape of their curves. TMB dissipated at faster rate than methanol during the early stages. However, after about 5 days the alcohol had become totally dissipated or absorbed into the wood. At this point TMB is present in the desiccator environment. The ratio methanol/boric acid after 4 hours was 16. This reduced to 9, 6 hours after the samples had been treated. The final ratio was 1.55.

TMB concentration in the desiccator environment dropped rapidly during the first 24 hours after treatment. Desiccator readings for TMB were 426 ppm, 5 minutes after the treatments. The reading dropped to 20 ppm, 22 hours after treatment. After this time, a slight increase in the concentration of TMB in the desiccator was observed dropping again to 5 ppm after 9 days. No explanation is available to explain this deviation other than experimental error in the sampling. Nevertheless, the trend of decreasing concentration is clear for both TMB and methanol. If the first 24 hours data is considered only, a curve fit gives an r² value (coefficient of correlation) of over 0.9.

The rate of change in concentrations of TMB and methanol within the desiccator are different. Methanol concentrations increased in the first hour of the experiment. The ratio of methanol/boric acid at this point in time was 9. The concentration of methanol then dropped following a logarithmic curve with an r² fit of over 0.9. However, the ratio increased in the first 4 hours to 16.3. The data suggests that TMB is liberated into the space of the container (in this case a desiccator) in a shorter time than methanol. This is explained by the hydrolysis of the TMB in the wood. Methanol is emitted from the wood in the first hour and its dissipation is initially slower than TMB but complete at the end of the experiment. The slope of the curve in the case of TMB suggests a proximity to an asymptotic curve when the TMB concentration in the desiccator is approximately 5 ppm. Regression analysis of TMB and methanol concentration against time gives correlation coefficients, r², of over 0.9.

An analysis was made of the wood samples at 12% moisture content. As expected, samples were not totally penetrated. The mean percentage TMB penetration was 51% with a range from 30% to 57%. The mean depth of penetration was 8.67 mm. The mean retention of boric acid was 1.69% wt/wt after storage was considered complete, 8 days after treatment. Changes in the volume of the samples of 1.03% were noted. This may be due to a combination of boric acid deposition, methanol adsorption or changes in moisture content due to changing environmental conditions. Although it was known that total penetration of TMB was unachievable in samples at 12% when treated by the present process, methanol produced by TMB hydrolysis was found in the core of the samples. This suggests that a diffusion process takes place with methanol. The results indicate that 44% of the methanol produced was adsorbed by the wood. This percentage was found after submitting wood samples to a flow of 0.25 l/minute for 24 hours.

Further embodiments of invention will now be described with reference to the following Examples. In Examples 6 and 7 which are embodiments of the second aspect of the invention, the following abbreviations are used:
LP=Lowry process; and
MC=moisture content.

### Example 6

Fifteen matched and end-sealed blocks of radiata pine sapwood (including heartwood) measuring 45×90×150 mm were vacuum/pressure impregnated with 1.25, 2.5 and 5% TMB in kerosene. They were treated with a modified Lowry schedule comprising the following steps:
(a) flooding the vessel with preservative (10 kPa);
(b) applying pressure at 35 kPa for 10 minutes;
(c) emptying the vessel; and
(d) evacuating the vessel −90 kPa for 45 minutes.

A set of 5 matched samples, all conditioned to same moisture content were treated by dipping for 30 seconds in TMB. They were then transferred in block into a polyester bag, sealed and stored for 5 days to allow diffusion of vapour and dissipation of chemicals from the head space of the bags. The moisture content of all the samples ranged from between 10 to 12%. The results are shown in Table 2 below.

TABLE 1
Penetration of TMB in wood samples of radiata pine treated
either by the Lowry process or by dipping

| Number of | Moisture | Treatment | Solution strength | Gross uptake | Net uptake | Boric acid | |
|---|---|---|---|---|---|---|---|
| replicates | content % | Type | % TMB (vol/vol) | (l/m³) | (l/m³) | equivalent % | Penetration* % |
| 5 | 10-12 | LP | 5.00 | 92 | 40 | 0.53 | 85 |
| | | | | (57.9) | (27.9) | (62.9) | (16.1) |
| 5 | 10-12 | LP | 2.50 | 76 | 33 | 0.21 | 80 |
| | | | | (34.2) | (13.6) | (38.3) | (20.0) |
| 5 | 10-12 | LP | 1.25 | 87 | 39 | 0.13 | 95 |
| | | | | (37.0) | (21.1) | (39.6) | (6.89) |
| 5 | 10-12 | Dipping | Pure | | 6.04 | 1.15 | 46 |
| | | | 100 | | (15.8) | (16.8) | (13.0) |

*Coefficients of variations are given in parenthesis.
*Boric acid penetration is indicated by spot-testing. The spot-test is sensitive to concentrations of boric acid greater than 0.2% wt/wt H₃BO₃

Sapwood samples treated by LP achieved over 90% penetration in all cases. One of the variables affecting treatment was the very low pressure used in the schedule. This was selected with the objective of optimising treatment by reducing net uptake. In other trials, total penetration was achieved in matched samples where pressure and net uptake was slightly higher.

Samples treated by dipping displayed poorer penetration (46%), despite a considerably higher boric acid equivalent retention than samples treated by LP. The penetration and boric acid loadings obtained following momentary immersion and dissipation storage were as expected, given the high moisture content of these samples. The improvement in penetration of TMB in wood treated by LP arises from a synergy in using non-polar solvents. Non-polar solvents are substantially immiscible and repellent to water. During pressure impregnation, the non-polar solvent protects the TMB from intimate contact of water contained in the wood cell wall. This enables the TMB to become totally dispersed throughout the wood before extensive hydrolysis can occur. TMB eventually penetrates the cell wall where rapid hydrolysis takes place according to equation (1) above. After preservative kickback and emptying of the treatment vessel there is almost total hydrolysis of TMB in the wood facilitating the safe removal of timber from the vessel without incurring the high cost and long time period required for recovering unreacted TMB.

### Example 7

Wood samples conditioned to either 13% or 20% moisture content were treated by LP using 2.5% TMB (vol/vol) dissolved in kerosene. In these treatments, oil was incorporated into the kerosene in various proportions ranging from 30, 50 or 70% of the carrier composition. The oil selected for these treatments had a viscosity of 55 centipoises at 20° C. and a density of 0.88 g/cm³ at the same temperature.

The samples were treated using alternative schedules. The pressures and times were varied according to viscosity of the carrier. These are shown in Table 3 below.

Table 3 summarises the penetration of TMB according to the proportion of oil used in the carrier and the pressure applied during treatment. It also shows the penetration of the carrier as a percentage of the total cross-section and as a percentage of the sapwood portion of the sample.

TABLE 2
Penetration of TMB according the proportion of oil in the carrier in
radiata pine treated with TMB by LP

| | | Pressure time | Gross Up | Net Up | | | Carrier | Corrected |
|---|---|---|---|---|---|---|---|---|
| MC % | % oil | kPa/min | (l/m³) | (l/m³) | BAE % | Penetrat. % | Penetrat. % | Penetrat. % |
| 13 | 30 | 35/5 | 86 | 46.7 | 0.3 | 80 | 85 | 94 |
| | | | (42.3) | (28.9) | (48.6) | (19.6) | (19.5) | (5.5) |
| 13 | 50 | 70/5 | 185 | 125 | 0.6 | 79 | 86 | 92 |
| | | | (76.8) | (49.2) | (79.3) | (26.9) | (21.5) | (7.2) |
| 13 | 70 | 105/10 | 97 | 76 | 0.3 | 66 | 68 | 96 |
| | | | (59.1) | (56.7) | (62.1) | (30.3) | (25.6) | (5.7) |
| 13 | 30 | 70/3 | 110 | 56 | 0.4 | 85 | 92 | 93 |
| | | | (47.9) | (27.2) | (53.9) | (18.5) | (20.4) | (6.8) |
| 20 | 30 | 35/5 | 105 | 52 | 0.3 | 42 | 85 | 51 |
| | | | (48.0) | (23.0) | (52.0) | (12.9) | (19.5) | (21.9) |
| 20 | 50 | 70/5 | 157 | 83 | 0.4 | 48 | 92 | 57 |
| | | | (57.1) | (28.8) | (58.8) | (32.2) | (19.9) | (29.8) |

TMB penetrations of 80% were obtained in wood samples treated with a solution of 30% of oil in kerosene. However, the sapwood proportion of the sample achieved 94% penetration. The carrier penetrated 85% of the wood sample. This indicates that there was some TMB hydrolysis and subsequent screening of TMB due to moisture in the wood sample.

Total penetration decreases as the proportion of oil in the carrier increases. However, the amount of sapwood treated is similar. The screening effect is approximately 2 to 7% of the penetration of the carrier. Matched wood samples conditioned to between 17-19% moisture content achieved penetrations of the order of 55% (±10%).

Further embodiments of the third aspect of the invention will now be described with reference to the following Examples.

### Example 8

Trimethoxy boroxine was diluted in kerosene and oil to provide solutions of 1-2% (vol/vol). End-sealed blocks of radiata pine sapwood (with included heartwood) measuring 45×90×150 mm were vacuum/pressure impregnated. They were treated with a modified Lowry schedule comprising the following steps:
(a) flooding the vessel with preservative (10 kPa);
(b) applying pressure at 35 kPa for 10 minutes;
(c) emptying the vessel; and
(d) evacuating the vessel −90 kPa for 45 minutes.

The wood samples were weighed before and after treatment and the volume of each sample measured. Preservative uptake calculations indicated a new preservative uptake of 32 l/m³. Cross-cutting of samples and spot-testing for boric acid distribution in the cross-section of the wood indicated total preservative penetration. The spot-test reagent used was curcamin/salysilicic acid as described in AS 1604.

### Example 9

Boric oxide was refluxed in trimethyl borate for 9 hours until dissolved to form a high-boiling point viscous mixture of trimethoxy boroxine and polyborate. An anionic surfactant was added to the solution and then dispersed in kerosene to provide a 2-3% dispersion. A similar preparation substituted one third of the kerosene with an oil which had a viscosity of 55 centipoises at 20° C. and a density of 0.88 g/cm³ at the same temperature.

The preservatives were applied to end-sealed blocks of radiata pine sapwood measuring 350×100×50 mm using a Lowry treatment schedule as follows:
(a) flooding the vessel with preservative (10 kPa);
(b) applying pressure at 35 kPa for 10 minutes;
(c) emptying the vessel; and
(d) evacuating the vessel −90 kPa for 45 minutes.

Total preservative penetration was achieved with both preservative systems, for preservative uptakes of 35 and 49 l/m³ respectively for the kerosene carrier and 33:66 oil:kerosene carrier. The moisture content of wood samples ranged from 10-14%.

### Example 10

Boric acid was added progressively to trimethyl borate and refluxed for 12 hours at 130° C. until dissolved. When cooled, a glassy solid was formed which became tacky and finally melted when gently warmed to approximately 30° C.

Five blocks of radiata-pine sapwood were exposed in unsterile moist soil to cause a rise in wood moisture content and the onset of early stages of decay. 5 mm diameter holes were drilled into the centre of each block at 100 mm centres. The holes were filled with the solid preservative, by melting the preservative and injecting the solution into the holes. On cooling, the solutions solidified in the holes. The blocks were wrapped in polythene and left for 4 months.

The blocks were then cut longitudinally and spot-tested with curcumin/salysilicic acid (AS 1604) to determine boron distribution. The results indicated substantial movement of boric acid from the drilled holes.

### Example 11

The glassy solid manufactured in Example 10 was dissolved in TMB to form a solution with a viscosity of approximately 100 centipoise. Samples of particle-board (a panel product manufactured from small chips) measuring 100×100×18 mm were edge sealed with epoxy resin and pressure impregnated with the solution using a Bethell process.

The schedule used comprised the following steps:
(a) evacuating the board in a vessel (−85 kPa—15 minutes);
(b) flooding the vessel with preservative;
(c) raising the pressure to 35 kPa (gauge) for 5 minutes;
(d) releasing pressure and emptying the vessel; and
(e) evacuating the cylinder (−85 kPa—45 minutes).

Total preservative penetration was achieved with this boron rich solution with no concomitant swelling of the board product. The mean preservative uptake was 61 l/m³.

Those skilled in the art will appreciate that the invention described herein is susceptible to variations and modifications other than those specifically described. It is to be understood that the invention includes all such variations and modifications which fall within its spirit and scope.

1. A process for treating wood comprising applying to the surface of the wood a boron based preservative which reacts with moisture within the wood to form a boron compound and alcohol and subjecting the wood with the applied preservative to a substantially moisture-free and enclosed environment for a period sufficient for the applied preservative to be absorbed into the wood and to produce the boron compound on reaction with the moisture in the wood and for the alcohol by-product of the reaction to be adsorbed within the wood structure.

2. A process according to claim 1, wherein, prior to the application of the boron based preservative to the wood, the wood is dried to reduce the moisture content of the wood.

3. A process according to claim 1, wherein the substantially moisture-free and enclosed environment to which the wood is subjected following application of the boron based preservative is such as to prevent the ingress of moisture into the treated timber, as may be provided from humidity in the atmosphere, and to substantially prevent the evaporation of the applied preservative from the wood into the atmosphere.

4. A process according to claim 3, wherein the wood with the applied preservative is introduced to a container or other preformed envelope, such as of steel or plastics, which is then sealed to provide the substantially moisture free and enclosed environment, or is wrapped to exclude atmosphere and thereby provide the substantially moisture free and enclosed environment.

5. A process according to claim 4, wherein the wood is wrapped in a plastics material selected from polyethylene film, polyester film, preferably polyethylene terephthalate (PET) film.

6. A process according to claim 5, wherein the wood is wrapped in a heat sealable co-extruded PET film, preferably having a thickness in the range of 15 to 30 μm.

7. A process according to claim 1, wherein the period of retention in the substantially moisture free and enclosed environment at ambient temperature and pressure is less than 3 days, preferably less than about 24 hours.

8. A process according to claim 1, wherein the moisture content of the wood is about 6% by weight or less of the oven dry weight of the wood.

9. A process according to claim 1, wherein the boron based preservative is TMB or a combination of TMB and methanol at or about the azeotropic composition thereof, or is triethyl borate.

10. A process according to claim 1, wherein the boron based preservative includes one or more additives selected from additives to enhance fire-proofing attributes, such as a compatible compound of zinc, additives to enhance activity, such as waxes, resins, oils and oil-based pigments which improve the water repellency of timber surfaces and may improve the colour and aesthetic appeal of the treated timber, and dimension stabilising chemicals such as acetic anhydride.

11. A process according to claim 1, wherein the boron based preservative is applied to the surface of the wood by pressure impregnation, vacuum/pressure impregnation, dipping, insizing and dipping, soaking, spraying/atomizing/fogging, electrostatic spraying, vaporising, evacuation and vapour or gaseous application, brushing, rolling and compression rolling.

12. A process according to claim 11, wherein the boron based preservative is applied to the wood by dipping for a period of about 2 minute or less, preferably about 1 minute or less, more preferably about 30 seconds or less and most preferably about 15 seconds or less.

13. A process according to claim 1, wherein following treatment of the wood the wood is surface treated, for example, with a resin, to immobilize the boron.

14. A process according to claim 1, wherein the boron based preservative is a light organic solvent wood preservative comprising a trialkyl borate and a non-polar carrier.

15. A process according to claim 14, wherein the trialkyl borates is one having C₁₋₂₀ alkyl, preferably C₁₋₉ alkyl, more preferably C₁₋₆ alkyl groups and most preferably TMB or triethyl borate.

16. A process according to claim 14, wherein the non-polar carrier is a non-polar solvent selected from aliphatic or aromatic hydrocarbons and heterocycles or derivatives thereof, preferably kerosene, petroleum or turpentine; an oil; or mixtures thereof.

17. A process according to claim 14, wherein the light organic solvent wood preservative further includes one of more additives selected from water repellents, such as waxes, resins or polymers, for example, polyethylene glycol; dimensional stabilisers, such as acetic anhydride; fire retardants, such as zinc compounds; mildewicides/fungicides; insecticides, such as, pyrethroids or triazoles; mouldicides; dyes and pigments.

18. A process according to claim 14, wherein the wood to be treated has a moisture content of from 10-14%.

19. A process according to claim 1, wherein the boron based preservative is a boroxine and/or a polyborate.

20. A process according to claim 19, wherein the boroxine has a general formula (I): 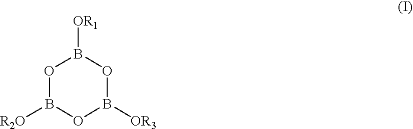
wherein R₁, R₂, and R₃ may be the same or different and are selected from optionally substituted alkyl, optionally substituted alkenyl, optionally substituted alkynyl, optionally substituted cycloalkyl, optionally substituted cycloalkenyl, optionally substituted cycloalkynyl, optionally substituted aryl or optionally substituted heterocycyl.

21. A process according to claim 20, wherein R₁, R₂, and R₃ are C₁₋₁₀ alkyl or phenol.

22. A process according to claim 19, wherein the polyborate has the general formula (II): 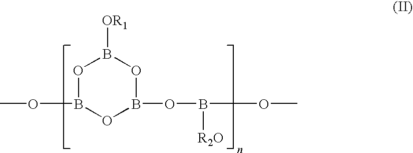
wherein R₁ and R₂ may be the same or different and are selected from optionally substituted alkyl, optionally substituted alkenyl, optionally substituted alkynyl, optionally substituted cycloalkyl, optionally substituted cycloalkenyl, optionally substituted cycloalkynyl, optionally substituted aryl or optionally substituted heterocycyl.

23. A process according to claim 22, wherein R₁ and R₂ are C₁₋₁₀ alkyl or phenol.

24. A process according to claim 19, wherein the boron based preservative is applied to the wood alone, in the form of an emulsion, or in combination with a suitable carrier which may be polar or non-polar and which is selected from water, alcohols, aromatic or aliphatic solvents or oils.

25. A process according to claim 19, wherein the boron based preservative includes one or more additives selected from water repellants, such as waxes, resins or polymers, such as polyethylene glycol; dimensional stabilisers, such as acetic anhydride; fire retardants, such as zinc compounds; mildewicides; fungicides/insecticides; such as pyrethroids or triazoles; mouldicides; dyes and pigments.

26-35. (canceled)
